(19) United States
(12) Patent Application Publication
(10) Pub. No.: US 2024/0321622 A1
(43) Pub. Date: Sep. 26, 2024

(54) ADSORPTION DEVICE FOR REFLOW PROCESS AND METHOD OF ATTACHING CONNECTION BUMP USING THE SAME, AND VACUUM JIG FOR SEMICONDUCTOR PACKAGE

(71) Applicant: SAMSUNG ELECTRONICS CO., LTD., SUWON-SI (KR)

(72) Inventor: YOUNG-JA KIM, Suwon-si (KR)

(21) Appl. No.: 18/474,455

(22) Filed: Sep. 26, 2023

(30) Foreign Application Priority Data
Mar. 24, 2023 (KR) 10-2023-0038731

(51) Int. Cl. H01L 21/683; H01L 21/60

(52) U.S. Cl. CPC H01L 21/6838; H01L 21/60; H01L 24/16; H01L 24/32; H01L 24/73; H01L 25/0657; H01L 2224/16227; H01L 2224/32225; H01L 2224/73204; H01L 2225/06506; H01L 2225/0651; H01L 2225/06562

(57) ABSTRACT

An adsorption device for a reflow process according to an embodiment is coupled to a semiconductor package to form a reflow assembly in a reflow process. The semiconductor package includes a substrate and a semiconductor chip disposed at one surface of the substrate. The adsorption device for the reflow process includes a main body and a pressure control member. The main body includes an inner space portion and includes a bottom portion and a substrate adsorption portion that protrudes from the bottom portion to be adhered to the one surface of the substrate in an outer region of the semiconductor chip by a negative pressure. The pressure control member maintains a pressure of the inner space portion.

### CROSS-REFERENCE TO RELATED APPLICATION

This application claims priority to and the benefit of Korean Patent Application No. 10-2023-0038731 filed in the Korean Intellectual Property Office on Mar. 24, 2023, the entire contents of which are incorporated herein by reference.

### BACKGROUND

### (a) Field

The present disclosure relates to an adsorption device for a reflow process, a method of attaching a connection bump using the same, and a vacuum jig for a semiconductor package.

### (b) Description of the Related Art

A semiconductor device may be miniaturized and may perform various functions so that the semiconductor device is widely used in various electronic industries. With development of the electronic industry, research on packaging technology for the semiconductor device continues.

Various components constituting the semiconductor device may be mounted on a substrate using a solder ball. A process of attaching the solder ball may include a process of disposing the solder ball on a pad and a reflow process of bonding, attaching, or coupling the solder ball to the pad by applying heat to the solder ball. Since the solder ball is directly related to mounting of the semiconductor device, a defect of the solder ball may have a great effect on productivity and reliability of the semiconductor device. Accordingly, a defect inspection on whether the solder ball is properly attached is performed after the process of disposing the solder ball, and then the reflow process is performed.

However, even if a defect inspection of the solder ball is performed before the reflow process is performed, a defect such as separation, movement, overlapping, or the like of the solder ball may occur due to deformation (warpage) due to a difference in thermal expansion of a substrate included in a semiconductor package during the reflow process. Changing a design or equipment by predicting the deformation due to the difference in thermal expansion of the substrate that occurs during the reflow process is a burden on the process, and even if the design or the equipment is changed, there is a limit to preventing the defect of the solder ball. Accordingly, it is required to control the deformation due to the difference in thermal expansion of the substrate in the reflow process.

### SUMMARY

Embodiments of the disclosure relate to an adsorption device for a reflow process, a method for attaching a connection bump using the adsorption device for the reflow process, and a vacuum jig for a semiconductor package capable of improving productivity and reliability of a semiconductor package.

According to an embodiment of the present disclosure, an adsorption device includes a main body that includes an inner space portion, a bottom portion, and a substrate adsorption portion that protrudes from the bottom portion, wherein the substrate adsorption portion is configured to adhere to a first surface of a substrate by a negative pressure, and a pressure control member that maintains a pressure of the inner space portion.

A vacuum jig for a semiconductor package according to an embodiment may include: a main body that includes an inner space portion and a bottom portion and a substrate adsorption portion protruding from the bottom portion, wherein the substrate adsorption portion includes one or more adsorption holes; and a vacuum control member configured to control a vacuum state of the inner space portion.

A method for forming a connection bump according to an embodiment includes: forming a reflow assembly by coupling an adsorption device to a semiconductor package including a substrate and a semiconductor chip disposed on a first surface of the substrate; forming the connection bump on a second surface of the substrate opposite the first surface; performing a reflow process of coupling the connection bump to the second surface of the substrate by applying heat to the connection bump; and separating the adsorption device from the semiconductor package. In the forming of the reflow assembly, a substrate adsorption portion of the adsorption device is adhered to an outer region of the semiconductor chip on the first surface of the substrate.

### BRIEF DESCRIPTION OF THE DRAWINGS

FIG. 1 is a cross-sectional view schematically illustrating a reflow assembly in which an adsorption device for a reflow process is coupled to a semiconductor package according to an embodiment.

FIG. 2A is a plane view schematically illustrating the semiconductor package shown in FIG. 1.

FIG. 2B is a plane view schematically illustrating the adsorption device for the reflow process shown in FIG. 1.

FIGS. 3A to 3E are cross-sectional views illustrating a method for attaching a connection bump including the reflow process using the adsorption device for the reflow process according to the embodiment.

FIG. 4 is a cross-sectional view schematically illustrating a reflow assembly in which an adsorption device for a reflow process is coupled to a semiconductor package according to another embodiment.

FIG. 5 is a plane view schematically illustrating the adsorption device for the reflow process according to another embodiment.

FIG. 6 is a cross-sectional view schematically illustrating a reflow assembly in which an adsorption device for a reflow process is coupled to a semiconductor package according to another embodiment.

FIG. 7 is a cross-sectional view schematically illustrating a reflow assembly in which an adsorption device for a reflow process is coupled to a semiconductor package according to another embodiment.

FIG. 8 is a plane view schematically illustrating a fixing portion of the adsorption device for the reflow process and the semiconductor package shown in FIG. 7.

FIG. 9 is a cross-sectional view schematically illustrating a reflow assembly in which an adsorption device for a reflow process is coupled to a semiconductor package according to another embodiment.

FIG. 10 is a plane view schematically illustrating an adsorption device for a reflow process according to a modified example.

FIG. 11 is a cross-sectional view schematically illustrating an adsorption device for a reflow process according to another embodiment.

FIG. 12 is a cross-sectional view schematically illustrating a reflow assembly in which the adsorption device for the reflow process according to the embodiment is coupled to a semiconductor package according to a modified example.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those elements illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below an element or a portion, and does not necessarily mean disposed on an upper side of an element or a portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

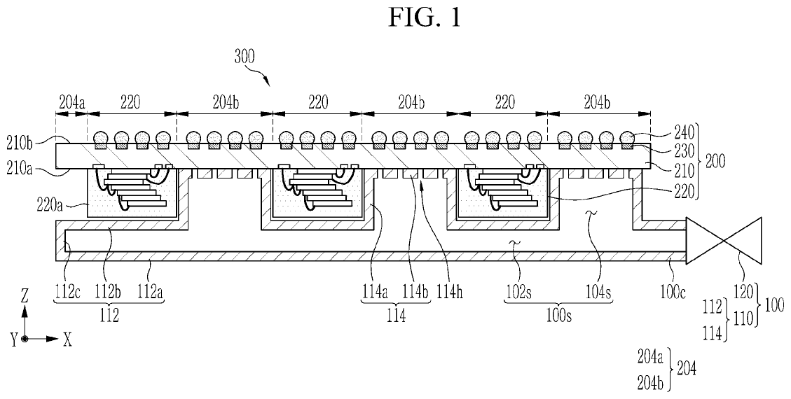

Hereinafter, referring to FIGS. 1, 2A, and 2B, and FIGS. 3A to 3E, an adsorption device for a reflow process and a method for attaching a connection bump using the same according to an embodiment will be described in detail.

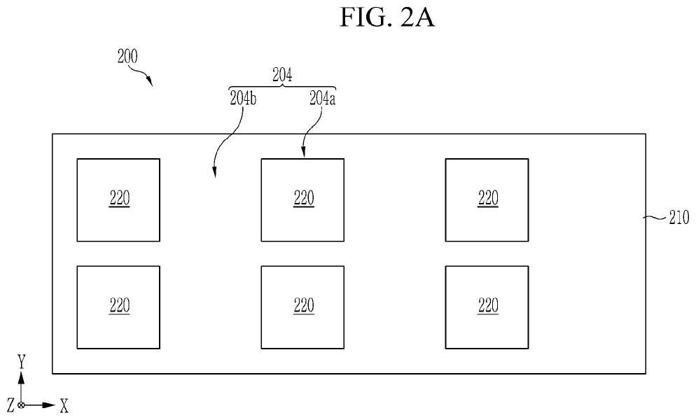

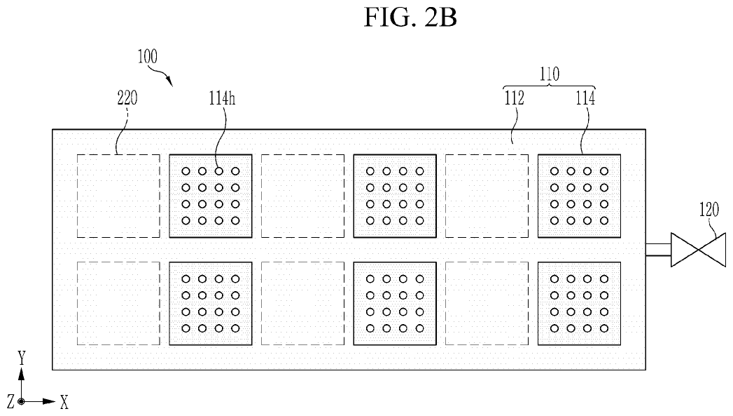

FIG. 1 is a cross-sectional view schematically illustrating a reflow assembly in which an adsorption device for a reflow process is coupled to a semiconductor package according to an embodiment. FIG. 2A is a plane view schematically illustrating the semiconductor package shown in FIG. 1, and FIG. 2B is a plane view schematically illustrating the adsorption device for the reflow process shown in FIG. 1. FIG. 2A shows an upper surface of the semiconductor package facing the adsorption device for the reflow process, and FIG. 2B shows an upper surface of the adsorption device for the reflow process facing the semiconductor package. For a clear understanding, in FIG. 2B, a region where a semiconductor chip included in the semiconductor package is disposed is indicated by a dotted line.

Referring to FIG. 1, the adsorption device 100 for the reflow process according to an embodiment includes a main body 110 having an inner space portion 100s and a pressure control member 120 for controlling a pressure of the inner space portion 100s. The adsorption device 100 for the reflow process may be referred to as the adhesion device for the reflow process. The inner space portion 100s may include a first space portion 104s and a second space portion 102s connected to a connection portion 100c that is connected to the first space portion 104s and the pressure control member 120. At least a portion of the main body 110 may be adsorbed to a surface at which a semiconductor chip 220 is disposed at a substrate 210 included in the semiconductor package 200 by the pressure control member 120.

Hereinafter, an example of the semiconductor package 200 to which the adsorption device 100 according to the embodiment may be applied will be described in detail with reference to FIGS. 1 and 2A, and then the adsorption device 100 according to the embodiment will be described in detail with reference to FIGS. 1, 2A, and 2B.

Referring to FIGS. 1, 2A, and 2B, the semiconductor package 200 to which the adsorption device 100 according to the embodiment may be applied may include a substrate 210, a semiconductor chip 220 disposed on one surface (hereinafter, an upper surface) 210a of the substrate 210, and a bonding pad 230 disposed on the other surface (hereinafter, a lower surface) 210b of the substrate 210. The semiconductor package 200 may further include a connection bump 240 connected to or bonded to a bonding pad 230.

In an embodiment, the substrate 210 may include various boards that support the semiconductor chip 220 and are electrically connected to the semiconductor chip 220, where, for example, the substrate 210 may include a printed circuit board, a redistribution board, an interposer board, and the like.

In an embodiment, the bonding pad 230 and the connection bump 240 connected to the bonding pad 230 may be disposed on the lower surface 210b of the substrate 210, and the semiconductor chip 220 may be mounted on the upper surface 210a of the substrate 210. Here, the upper surface 210a of the substrate 210 may be defined as a surface where the semiconductor chip 220 is disposed, and the lower surface 210b of the substrate 210 may be defined as a surface opposite to the surface where the semiconductor chip 220 is disposed or an outer surface where the connection bump 240 is disposed.

In various embodiments, a bonding pad 230 disposed on the lower surface 210b of the substrate 210 may be a pad to which the connection bump 240 is connected. The connection bump 240 may be utilized for physically and electrically connecting the semiconductor package 200 to another substrate, where the bonding pad 230 may include a solder material. For example, the connection bump 240 may have various shapes, including, but not limited to, a ball, a land, a pin, and the like. The connection bump 240 may include tin (Sn) or an alloy (e.g., a Sn—Ag—Cu alloy) including tin (Sn). For example, the connection bumps 240 may be formed of a solder ball, and the bonding pad 230 may be formed of a solder ball pad. However, the embodiment is not limited thereto, and the bonding pad 230 and the connection bump 240 may have various shapes, and include various materials.

The semiconductor chip 220 disposed on the upper surface 210a of the substrate 210 may include a memory chip for storing data, a non-memory chip for performing calculations, processing, or controlling information, or a composite semiconductor chip in which a memory portion and a non-memory portion are combined, or may include a plurality of chips. For example, a memory chip may be a volatile memory such as a dynamic random access memory (DRAM), a static random access memory (SRAM), or the like, or a non-volatile memory such as a NAND flash memory system or the like. For example, the non-memory chip or the composite semiconductor chip may include a central processing unit (CPU), a graphics processing unit (GPU), a neural processing unit (NPU), a microcontroller unit (MCU), an application processor (AP), an application-specific integrated circuit (ASIC), an image sensor, or the like. As described above, the embodiment is not limited to a type of the semiconductor chip 220 or the like.

In an embodiment, the semiconductor chip 220 may be configured as a single chip or may be configured in a form of a chiplet including a plurality of chips. As described above, the embodiment is not limited to a shape, the number, a disposition, or the like of the semiconductor chips 220.

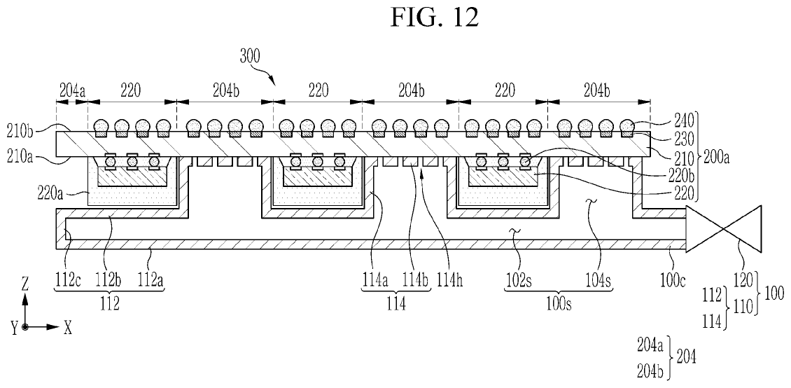

For example, the drawings illustrate that the semiconductor chip 220 is mounted on the upper surface 210a of the substrate 210 by wire bonding. However, the embodiment is not limited thereto, and another embodiment will be described in detail with reference to FIG. 12.

An outer region 204 may be disposed outside the semiconductor chip 220 on the upper surface 210a of the substrate 210, where the outer region 204 may be to either or both sides of the semiconductor chip 220. The outer region 204 may refer to an empty space in which the semiconductor chip 220, a separate component, or the like is not disposed on the upper surface 210a of the substrate 210.

In an embodiment, the outer region 204 may include an edge region 204a provided along an outer edge of the plurality of semiconductor chips 220 to secure stability, and may include a dummy region 204b disposed at least on one side of the semiconductor chip 220, so that an additional semiconductor element, an additional semiconductor chip, an additional electronic component, or the like, can be disposed on the dummy region 204b. The dummy region 204b may have a relatively large area, so that the semiconductor element, the semiconductor chip, the electronic component, or the like is stably disposed. For example, a line width of the dummy region 204b may be greater than a line width of the edge region 204a.

For simple illustration and clear understanding, the drawings illustrate as an example that the dummy region 204b is disposed at one side (a right side of the drawings) of the semiconductor chip 220. However, the embodiment is not limited thereto, and a position, the number, or the like of the dummy region 204b may be variously modified.

Referring to FIGS. 1, 2A, and 2B, the adsorption device 100 according to the embodiment may have a structure in which the adsorption device 100 may be adsorbed to the semiconductor package 200 so that an integrated state with the semiconductor package 200 is maintained for a certain period of time. For example, the adsorption device 100 may have a structure in which the adsorption device 100 may be integrated with the semiconductor package 200 in a reflow process of an attachment process for attaching the connection bump 240, where the adsorption device 100 can move together with the semiconductor package 200. In addition, the adsorption device 100 may have a structure in which the adsorption device 100 may be separated from the semiconductor package 200 after the reflow process. The adsorption device 100 may be configured as a detachable unit that may be coupled to and separated from the semiconductor package 200.

In various embodiments, the adsorption device 100 may include a vacuum unit or a vacuum jig coupled to the semiconductor package 200 by a negative pressure (e.g., a vacuum pressure). The adsorption device 100 may be a structure that remains coupled to the semiconductor package 200 by the negative pressure (e.g., the vacuum pressure) during the reflow process, and may also be referred to as a vacuum unit, a vacuum jig, a vacuum transfer, a vacuum plate, or the like.

In various embodiments, the adsorption device 100 may include the main body 110 having the inner space portion 100s and the pressure control member 120 that controls the pressure of the inner space portion 100s. Here, the main body 110 may include a bottom portion 112 and a substrate adsorption portion 114 that protrudes from the bottom portion 112 and is adsorbed to the upper surface 210a of the substrate 210 in the outer region 204 by the negative pressure or the vacuum pressure. The inner space portion 100s may include a first space portion 104s disposed inside the substrate adsorption portion 114 and a second space portion 102s connected to a connection portion 100c that is connected to the first space portion 104s and the pressure control member 120.

The bottom portion 112 may constitute a lower outer portion of the adsorption device 100, so that the second space portion 102s is disposed inside the adsorption device 100, and may have a shape that entirely encloses the first space portion 104s except for a portion connected to the second space portion 102s and the connection portion 100c.

For example, the bottom portion 112 may include a first bottom portion 112a constituting a lower surface of the adsorption device 100, a second bottom portion 112b that is spaced apart from the first bottom portion 112a at a predetermined distance to be disposed parallel to the first bottom portion 112a and to be connected to the substrate adsorption portion 114, and a side portion 112c connecting the first bottom portion 112a to the second bottom portion 112b. The first bottom portion 112a may extend from a distal end of the semiconductor package 200 to the connection portion 100c at an end proximal to the pressure control member 120, where the first bottom portion 112a and second bottom portion 112b can form one or more second space portions 102s.

In various embodiments, the first bottom portion 112a may have a plate shape extending in a first direction (an X-axis direction in the drawings) and a second direction (a Y-axis direction in the drawings) to correspond to an entire region of the semiconductor package 200. For example, the first bottom portion 112a may be formed of a plate having the same or similar shape as that of the semiconductor package 200 and the same or similar area as that of the semiconductor package 200.

An outer edge of the second bottom portion 112b may be disposed to have the same or similar shape as that of an outer edge of the semiconductor package 200 and the same or similar area as that of the outer edge of the semiconductor package 200, and the substrate adsorption portion 114 may be disposed at the second bottom portion 112b. The second bottom portion 112b may be spaced apart from the first bottom portion 112a with the second space portion 102s interposed between the second bottom portion 112b and the first bottom portion 112a.

The side portion 112c may extend in a third direction (a Z-axis direction in the drawings) intersecting (e.g., orthogonal to) the first and second bottom portions 112a and 112b, so that all edges of the first and second bottom portions 112a and 112b are connected at a side portion 112c except for the connection portion 100c.

In addition, the substrate adsorption portion 114 may protrude from the bottom portion 112 (more specifically, the second bottom portion 112b). The substrate adsorption portion 114 may include a side portion 114a that extends in the third direction (the Z-axis direction in the drawings) intersecting (e.g., orthogonal to) the bottom portion 112 and constitutes a side surface of the substrate adsorption portion 114, and an adsorption portion 114b connected to the side portion 114a and configured to be adsorbed to the substrate 210.

The side portion 114a may be formed as a whole to separate a side surface of the first space portion 104s from the outside. A height of the side portion 114a or a thickness of the substrate adsorption portion 114 may be the same as or similar to a thickness of the semiconductor chip 220, so that the substrate adsorption portion 114 is stably adhered to the substrate 210 at the outer region 204 of the semiconductor chip 220. In a state in which the adsorption device 100 is coupled to the semiconductor package 200, the side portion 114a may be spaced apart from a side surface of the semiconductor chip 220, where a gap can be present between the side portion 114a and the semiconductor chip 220. Accordingly, it is possible to prevent the semiconductor chip 220 from being undesirably affected by the side portion 114a.

An adsorption hole 114h may be provided at the adsorption portion 114b. The adsorption hole 114 may be referred to as the adhesion hole. The adsorption hole 114h may be formed to pass through the adsorption portion 114b, and may be formed to fluidly communicate with the first space portion 104s. One or a plurality of adsorption holes 114h may be provided in one adsorption portion 114b. For example, at the one adsorption portion 114b, a plurality of adsorption holes 114h may have the same shape and the same size, and may be disposed at equal intervals within the adsorption portion 114b. When the plurality of adsorption holes 114h are provided, a difference in warpage due to a difference in pressure may be minimized. However, the embodiment is not limited thereto, and a shape, a disposition, an interval, or the like, of the adsorption holes 114h may be variously modified.

For example, a diameter or a width of the adsorption hole 114h may be about 10 micrometers (μm) to about 10 millimeters (mm). Here, the diameter or the width of the adsorption hole 114h may mean a maximum diameter or a maximum width. When the diameter or the width of the adsorption hole 114h is less than 10 μm, an adsorption force of the substrate adsorption portion 114 may not be sufficient. When the diameter or the width of the adsorption hole 114h exceeds 10 mm, a degree of deformation (warpage) may be different between a portion where the adsorption hole 114h is disposed and a portion where the adsorption hole 114h is not disposed, and a risk of vacuum breakage or a risk of leakage may be high. However, the above-described numerical range of the diameter or the width of the adsorption hole 114h is just presented as an example, and the embodiment is not limited thereto.

FIG. 2B illustrates that the adsorption hole 114h has a circular shape, but the embodiment is not limited thereto. The adsorption hole 114h may have various shapes such as an elliptical shape, a rounded shape, a polygonal shape, an irregular shape, and the like. In addition, although the drawings illustrate that the adsorption holes 114h have the same size, another embodiment may include the adsorption holes 114h having different sizes. In addition, although the drawings illustrate that the adsorption holes 114h have the same intervals, in another example, intervals of the adsorption holes 114h may be different from each other. Various other variations are also possible.

In an embodiment, the substrate adsorption portion 114 may be formed to correspond to at least a portion of the outer region 204, including the dummy regions 204b, where the semiconductor chip 220 is not disposed, so that the substrate adsorption portion 114 is adhered to the outer region 204 at the upper surface 210a of the substrate 210.

A region where the semiconductor chip 220 is disposed and the outer region 204 where the semiconductor chip 220 is not disposed in the substrate 210 are portions where degrees of thermal expansion may differ from each other depending on whether the semiconductor chip 220 is present. That is, the substrate 210 may be expanded relatively greater amount at the outer region 204 where the semiconductor chip 220 is not disposed. When a difference in thermal expansion occurs, the connection bump 240 may be easily separated, moved, or overlapped. This problem may occur even more when an area of the outer region 204 to which the semiconductor chip 220 is not attached is large or a portion to which the semiconductor chip 220 is not attached increases due to a defect or the like. In consideration of this, in various embodiments, the substrate adsorption portion 114, having a structure identical to or similar to the semiconductor chip 220, is adhered and coupled to the outer region 204. Then, the substrate adsorption portion 114 may serve as a kind of dummy chip or artificial chip.

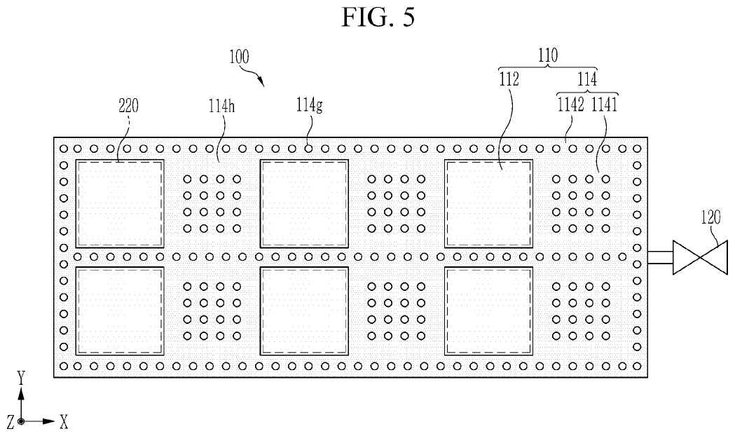

FIG. 2B illustrates that the substrate adsorption portion 114 can be positioned in register with the dummy region 204b. When the substrate adsorption portion 114 is attached to the dummy region 204b having a relatively large area, it is possible to effectively prevent a problem caused by a difference in thermal expansion rate that may occur due to the dummy region 204b. However, the substrate adsorption portion 114 may be disposed alone or additionally at a region other than the dummy region 204b, and this will be described in detail later with reference to FIG. 5.

For example, an area of the substrate adsorption portion 114 corresponding to an area of the dummy region 204b provided between the semiconductor chips 220 may be about 50% to about 95% (e.g., 80% to 95% or 80% to 90%) of the area of the dummy region 204b provided between the semiconductor chips 220. When the above ratio is less than 50%, it may be difficult for the substrate adsorption portion 114 to be stably adhered to the substrate 210. When the above ratio exceeds 90% (for example, 95%), a problem in which the substrate adsorption portion 114 undesirably affects or presses the semiconductor chip 220 may occur. However, the embodiment is not limited thereto, and the above ratio may have other values.

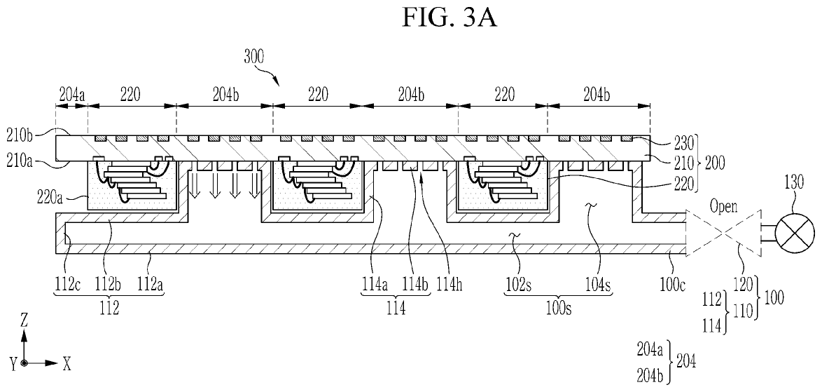

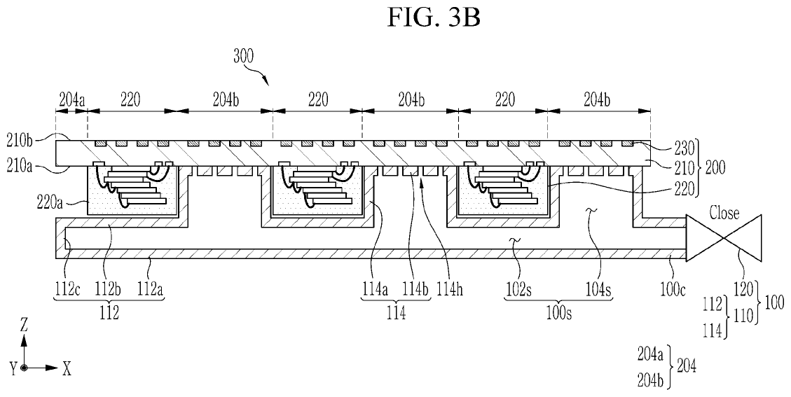

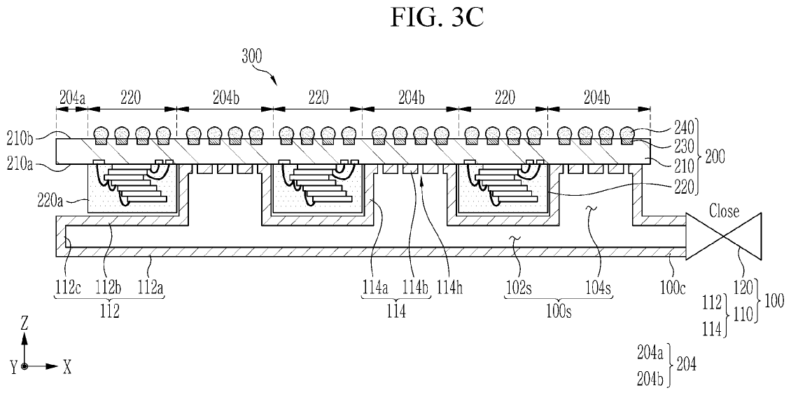

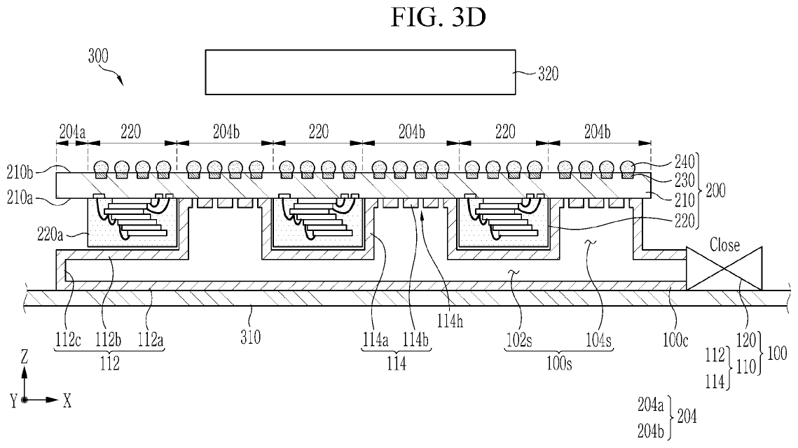

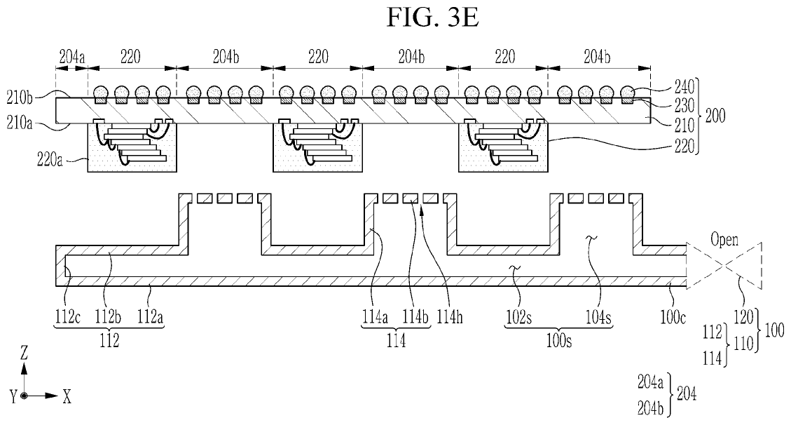

Referring to FIG. 3A, a region surrounded by the side portion 114a and the adsorption portion 114b may constitute the first space portion 104s, and a region surrounded by the first bottom portion 112a, the second bottom portion 112b, and the side portion 112c may constitute the second space portion 102s. A plurality of substrate adsorption portions 114 may be provided so that a plurality of first space portions 104s disposed inside the substrate adsorption portion 114 are provided, and the plurality of first space portions 104s may be connected to one or more second space portion 102s, and to the connection portion 100c in fluid communication with the pressure control member 120. When the second space portion 102s connecting the plurality of first space portions 104s is provided, a structure may be simplified by reducing the number of pressure control members 120. In addition, the pressure control member 120 may be freely disposed regardless of a position of the first space portion 104s, so that it is easy to configure the adsorption device 100, as a detachable unit.

The bottom portion 112 and the substrate adsorption portion 114 of the main body 110 may be positioned adjacent to the upper surface 210a of the substrate 210, where the semiconductor chip 220 is positioned to fix and support the semiconductor package 200. More specifically, the substrate adsorption portion 114 may be adhered to the upper surface 210a of the substrate 210 and the bottom portion 112 may be located adjacent to the semiconductor chip 220. The bottom portion 112 and the adsorption portion 114b of the main body 110 may not be disposed on the lower surface 210b of the substrate 210, where the connection bump 240 is disposed, so that the main body 110 and the connection bump 240 do not unnecessarily influence each other.

In various embodiments, the main body 110 may be made of a material that has constant rigidity and is maintained without deformation at a temperature at which the reflow process is performed, where for example, the main body 110 may be made of stainless steel, ceramic, or the like. The main body 110 may be made of a thermal conductive material having higher thermal conductivity than the substrate 210 or may further include a thermal conductive layer having higher thermal conductivity than the substrate 210. For example, the main body 110 may include a body portion made of stainless steel and a thermal conductive layer formed on the body portion. The thermal conductive layer may include various materials, and may include, for example, a metal such as copper or the like. When the main body 110 includes the thermal conductive material or the thermal conductive layer, heat may be effectively transferred or discharged through the main body 110 in the reflow process, so that thermal deformation of the substrate 210 is reduced or prevented. However, the embodiment is not limited thereto, and the main body 110 may be made of other materials.

The inner space portion 100s of the main body 110 may have an entirely closed structure except for the connection portion 100c or the pressure control member 120, and the adsorption holes 114h. A pressure of the inner space portion 100s may be adjusted by opening and closing the pressure control member 120, where the pressure control member 120 may include a valve. When the pressure control member 120 is configured as a valve, the pressure of the inner space portion 100s may be stably controlled with a simple structure. For example, the pressure control member 120 may be configured as a three-way valve, but the embodiment is not limited thereto.

The pressure control member 120 may have a structure that may be connected to and/or separated from a vacuum pump 130 of FIG. 3A, or may have a structure connected to the vacuum pump 130. The vacuum pump 130 may generate a negative or vacuum pressure in the inner space portion 100s to adhere the adsorption device 100 to the semiconductor package 200. In various embodiments, the pump 130 may be disconnected prior to the reflow process. Accordingly, a reflow assembly 300 including the adsorption device 100 may have a simple structure, so that mobility of the reflow assembly 300 is improved. However, the embodiment is not limited thereto, and a state in which the pump 130 is connected to the adsorption device 100 may be maintained during the reflow process.

In an embodiment, where the substrate adsorption portion 114 is disposed on the outer region 204 of the upper surface 210a of the substrate 210, the pressure control member 120 may be opened and the negative or vacuum pressure may be provided by the pump 130, so that the pressure within the inner space 100s is reduced relative to the pressure outside the adsorption device 100. When the inner space portion 100s is in a vacuum state, so that the substrate adsorption portion 114 is adhered to the upper surface 210a of the substrate 210, a pressure control member 120 may be closed to seal and maintain a vacuum state of the inner space portion 100s and maintain a state in which the substrate adsorption portion 114 is adhered to the substrate 210. In the reflow process, the pressure control member 120 may be maintained in a closed state, and after the reflow process, the pressure control member 120 may be opened to break vacuum of the inner space portion 100s, so that the adsorption device 100 is easily detached from the semiconductor package 200.

In various embodiments, the substrate adsorption portion 114 is partially formed to correspond to at least a portion of the outer region 204 where the semiconductor chip 220 is not disposed. Thus, it sufficiently prevents the warpage of the portion of the substrate 210 where the substrate adsorption portion 114 is located when a negative or vacuum pressure is provided. Accordingly, the adsorption device 100 may be stably attached to or joined with the semiconductor package 200 without providing a separate negative or vacuum pressure during the reflow process.

The pressure control member 120 may be disposed at various positions. For example, the adsorption device 100 may have a long axis edge (a major axis edge) and a short axis edge (a minor axis edge), and the pressure control member 120 may be disposed at the short axis edge of the adsorption device 100. This is in consideration that a guide member for guiding the reflow assembly 300 or the like may be mounted at the long axis edge of the adsorption device 100 or the reflow assembly 300 when the reflow process is performed. However, the embodiment is not limited thereto, and various modifications such as disposing the pressure control member 120 at the long axis edge are possible.

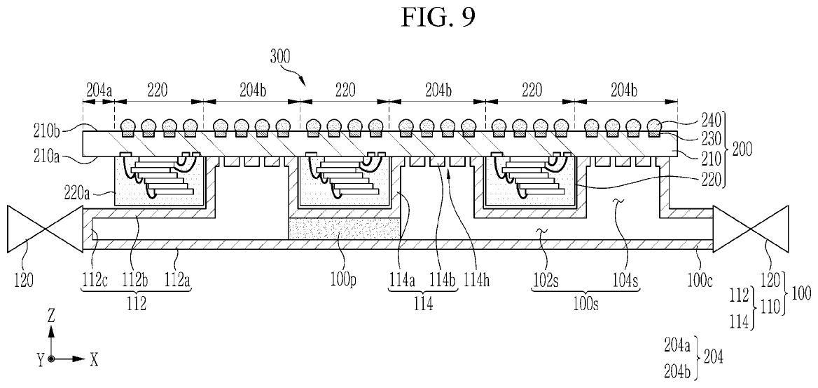

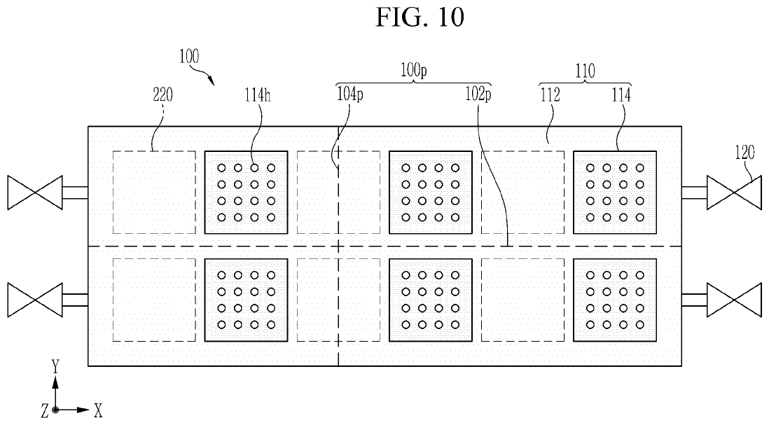

FIG. 2B illustrates that one second space portion 102s, one connection portion 100c, and one pressure control member 120 are each provided at the short axis edge disposed at one side of the adsorption device 100. Accordingly, a structure may be simplified by reducing the number of pressure control members 120. However, the embodiment is not limited thereto. Therefore, it is possible to maintain a pressure of the inner space portion 100s more stably by providing a plurality of second space portions 102s and/or a plurality of pressure control members 120. This will be described in detail later with reference to FIGS. 9 and 10.

In various embodiments, a negative pressure or vacuum pressure provided to the inner space portion 100s may be calculated in consideration of a size of the adsorption hole 114h, volume of the inner space portion 100s, mass of the adsorption device 100, mass of the semiconductor package 200, etc. In addition, the negative or vacuum pressure provided to the inner space portion 100s may be about 100 Pascals (Pa) to about 100 KPa (e.g., 100 Pa to 10 KPa). The negative or vacuum pressure may be limited to prevent an undesirable effect on the semiconductor package 200, while stably attaching the adsorption device 100 to the semiconductor package 200. However, the embodiment is not limited thereto, and the negative or vacuum pressure provided to the inner space portion 100s may have other values.

In various embodiments, the reflow process may be performed in a state in which the substrate adsorption portion 114 serving as the dummy chip or the artificial chip is adhered to the outer region 204 (e.g., the dummy region 204b) where the semiconductor chip 220 is not disposed. Accordingly, a degree of thermal expansion of the substrate 210 in the region where the semiconductor chip 220 is disposed may be controlled to be the same as or similar to a degree of thermal expansion of the outer region 204 where the semiconductor chip 220 is not disposed, such that thermal expansion may be consistent along the substrate 210. Therefore, in the reflow process, it is possible to fundamentally prevent a warpage phenomenon that may occur due to a difference in thermal expansion of the substrate 210 and an attachment defect such as unwanted separation, movement, or overlapping of the connection bump 240 due to the warpage phenomenon. As described above, according to the embodiment, productivity and reliability of the semiconductor package 200 may be improved.

For example, a problem caused by the difference in thermal expansion may appear larger in a capillary underfill (CUF) structure in which a sealing material 220a for sealing the semiconductor chip 220 is disposed below the semiconductor chip 220 compared with a case where the sealing material 220a is disposed as a whole. The adsorption device 100 according to the embodiment may be applied to the semiconductor package 200 having the capillary underfill structure so that the problem caused by the difference in thermal expansion is minimized.

In this case, deformation due to the difference in thermal expansion of the substrate 210 may be minimized or prevented in the reflow process in which substantial thermal deformation occurs. Accordingly, it may not be necessary to change a design of the semiconductor package 200 or equipment for manufacturing the semiconductor package 200 by predicting the deformation due to the difference in thermal expansion. Thus, design freedom and performance of the semiconductor package 200 may be improved.

In various embodiments, the adsorption device 100 can include the main body 110 having a bottom portion 112 and the substrate adsorption portion 114, and the pressure control member 120 for a vacuum unit or a vacuum jig structure that is attached to the semiconductor package 200 to be moved. Accordingly, the deformation due to the difference in thermal expansion of the substrate 210 that may occur in the reflow process may be minimized or prevented with a simple structure, and the adsorption device 100 may be easily separated by breaking the vacuum after the reflow process. A separate device for continuously providing a vacuum pressure to the inner space portion 100s of the adsorption device 100 may not be utilized during the reflow process. In addition, the embodiment may be easily applied to the reflow process performed using a conveyor belt without changing equipment. Accordingly, a burden on equipment may be reduced.

A method for attaching the connection bump 240 including the reflow process using the adsorption device 100 according to the above-described embodiment will be described in detail with reference to FIGS. 3A to 3E. FIGS. 3A to 3E are cross-sectional views illustrating the method for attaching the connection bump 240 including the reflow process using the adsorption device 100 according to the embodiment.

A method for attaching the connection bump 240 according to an embodiment includes a process of forming the reflow assembly 300 by coupling the adsorption device 100 to the semiconductor package 200, forming the connection bump 240 on the lower surface 210b of the substrate 210 included in the semiconductor package 200, applying heat to the connection bump 240, and separating the adsorption device 100 from the semiconductor package 200.

As shown in FIGS. 3A and 3B, the reflow assembly 300 may be formed by coupling or fixing the adsorption device 100 to the semiconductor package 200, where the adsorption device 100 can adhere to the upper surface 210a of the substrate 210. Where the adsorption device 100 is on the upper surface 210a of the substrate 210, the adsorption device 100 may be coupled to the semiconductor package 200 by creating a low pressure vacuum in the inner space portion 100s.

First, as shown in FIG. 3A, the adsorption device 100 may be positioned at the upper surface 210a of the substrate 210, and a negative pressure may be provided to the inner space portion 100s, where the pressure control member 120 is open, so that the inner space portion 100s is made into a vacuum state. For example, the pump 130 may be fluidly connected to the pressure control member 120 or the connection portion 100c, and the negative pressure may be created in the inner space portion 100s using the pump 130. Air may be exhausted through the adsorption hole 114h into the inner space portion 100s, so that the adsorption portion 114b of the substrate adsorption portion 114 adheres to the upper surface 210a of the substrate 210. In response to the substrate adsorption portion 114 adhering to the upper surface 210a of the substrate 210, as shown in FIG. 3B, the pressure control member 120 can be closed to maintain a vacuum in the inner space portion 100s and attachment of the substrate adsorption portion 114 to the upper surface 210a of the substrate 210.

In an embodiment, the pump 130 may be one or more various vacuum pumps capable of generating a vacuum in the inner space portion 100s. For example, the pump 130 may be a rotary pump, a diaphragm pump, a turbo pump, or the like. The pump 130 may be disconnected from the pressure control member 120 prior to the reflow process. Accordingly, the reflow assembly 300 including the adsorption device 100 may have a simple structure, so that mobility of the reflow assembly 300 can be improved. However, the embodiment is not limited thereto, and a state in which the pump 130 is connected to the adsorption device 100 may be maintained during the reflow process.

Subsequently, as shown in FIG. 3C, the connection bump 240 may be formed on the bonding pad 230 on the lower surface 210b of the substrate 210. Prior to the process of forming the connection bump 240 on the bonding pad 230, a process of applying a flux on the bonding pad 230 may be performed. In the process of placing the connection bump 240 on the bonding pad 230, the pressure control member 120 may remain closed.

In various embodiments, the connection bump 240 is placed on the semiconductor package 200 after forming the reflow assembly 300 by combining the adsorption device 100 with the semiconductor package 200. That is, in the process of forming the reflow assembly 300, the connection bump 240 may not be on the semiconductor package 200. The adsorption device 100 may be coupled to the semiconductor package 200 in a state in which the connection bump 240 is not provided, so that when the adsorption device 100 is coupled, unwanted influence on the connection bump 240 is avoided.

Coupling the adsorption device 100 to the semiconductor package 200 may be performed after forming the connection bump 240 on the semiconductor package 200 to reduce the time that the vacuum is maintained after the adsorption device 100 is coupled to the semiconductor package 200.

Subsequently, as shown in FIG. 3D, the reflow process may be performed on the reflow assembly 300 where the connection bump 240 is on the bonding pad 230. In the reflow process, heat may be applied to the connection bump 240 to couple the connection bump 240 to the bonding pad 230. In the reflow process, the pressure control member 120 may remain closed.

The reflow process according to the embodiment may be performed while the reflow assembly 300 moves on a conveyor belt 310. A heat source portion 320 may be provided above and/or below the conveyor belt 310 to apply heat to the connection bump 240. While a plurality of reflow assemblies 300 move on the conveyor belt 310, the connection bump 240 may be at least partially melted by the heat source portion 320 to be coupled to the bonding pad 230. As described above, when the reflow process is performed utilizing the conveyor belt 310 and the heat source portion 320, the reflow process may be sequentially performed on the plurality of reflow assemblies 300, so that productivity is improved.

The heat source portion 320 may include various structures or methods capable of providing heat to the connection bumps 240. For example, the heat source portion 320 may provide heat using infrared light, laser, hot air, or the like. Various other variations are possible.

The adsorption device 100 may have the vacuum unit or the vacuum jig structure configured to be coupled to the semiconductor package 200 to easily move on the conveyor belt 310. Because the adsorption device 100 does not need to have a vacuum line or similar connections for maintaining a vacuum state, there is no need to change equipment, so that a burden on equipment is reduced.

Subsequently, as shown in FIG. 3E, the adsorption device 100 may be separated from the semiconductor package 200 after the reflow process is completed. In the process of separating the adsorption device 100, vacuum in the inner space portion 100s may be broken by opening the pressure control member 120 and introducing air into the inner space portion 100s of the main body 110. The adsorption device 100 may be easily separated from the semiconductor package 200 without undesirably affecting the semiconductor package 200 by opening the pressure control member 120.

In various embodiments, the reflow process may be performed in a state in which the substrate adsorption portion 114, serving as the dummy chip or the artificial chip, is adhered to the outer region 204 (e.g., the dummy region 204b), where the semiconductor chip 220 is not disposed. Accordingly, it is possible to reduce or prevent the deformations that may occur due to a difference in thermal expansion of the substrate 210, an attachment defect of the connection bump 240 due to the deformation, and the like. In addition, after the reflow process, the adsorption device 100 may be easily separated from the semiconductor package 200 by vacuum breakage of the inner space portion 100s. Accordingly, productivity, reliability, design freedom, and performance of the semiconductor package 200 may be improved by the method without changing equipment.

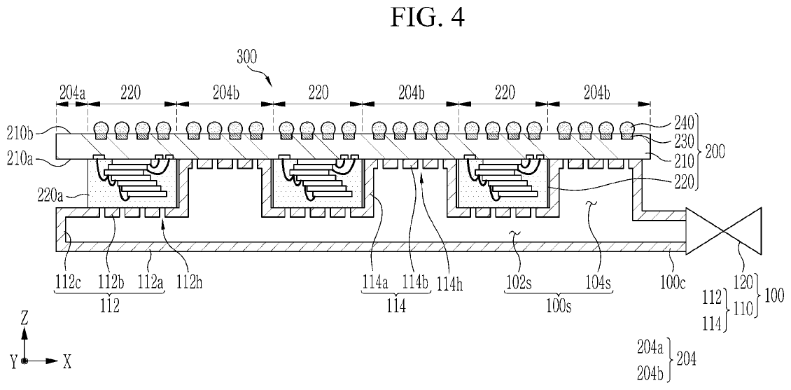

Hereinafter, an adsorption device and a reflow assembly including the adsorption device will be described in more detail with reference to FIGS. 4 to 12. A detailed description of a portion identical to or extremely similar to the portion already described will be omitted, and only another portion will be described in detail.

FIG. 4 is a cross-sectional view schematically illustrating the reflow assembly 300 in which the adsorption device is coupled to the semiconductor package according to another embodiment.

Referring to FIG. 4, the adsorption device 100 further includes a chip adsorption hole 112h formed at the bottom portion 112, so that the bottom portion 112 can be adhered to the semiconductor chip 220. More specifically, the chip adsorption hole 112h may be provided in the second bottom portion 112b adjoining the semiconductor chip 220. In various embodiments, the substrate adsorption portion 114 may be attached to the upper surface 210a of the substrate 210 by the adsorption hole 114h, and the bottom portion 112 may be attached to the upper surface of the semiconductor chip 220 by the chip adsorption hole 112h. When the substrate adsorption portion 114 and the bottom portion 112 of the adsorption device 100 are both attached to the semiconductor package 200, the adsorption area may be increased, so that the adsorption device 100 is more stably joined to the semiconductor package 200.

The chip adsorption hole 112h may be formed to pass through the second bottom portion 112b, and may be formed to fluidly communicate with the second space portion 102s. One or a plurality of chip adsorption holes 112h may be provided at the second bottom portion 112b corresponding to one semiconductor chip 220. For example, at the one semiconductor chip 220, the plurality of chip adsorption holes 112h may have the same shape and the same size, and may be disposed at equal intervals. When the plurality of chip adsorption holes 112h are provided, a difference in deformation due to a difference in pressure may be minimized.

For example, a diameter or a width of the chip adsorption hole 112h may be about 10 μm to about 10 mm. Here, the diameter or the width of the chip adsorption hole 112h may mean a maximum diameter or a maximum width. When the diameter or the width of the chip adsorption hole 112h is less than 10 μm, an adsorption force of the bottom portion 112 may not be sufficient. When the diameter or the width of the chip adsorption hole 112h exceeds 10 mm, a degree of deformation may be different between a portion where the chip adsorption hole 112h is disposed and a portion where the chip adsorption hole 112h is not disposed, and a risk of vacuum breakage or a risk of leakage may be high. However, the above-described numerical range of the diameter or the width of the chip adsorption hole 112h is only presented as an example, and the embodiment is not limited thereto.

A size of the chip adsorption hole 112h may be the same as or larger or smaller than a size of the adsorption hole 114h. The chip adsorption hole 112h may have any of various planar shapes, such as a circular shape, an elliptical shape, a rounded shape, a polygonal shape, an irregular shape, and the like. A planar shape of the chip adsorption hole 112h may be the same as or different from that of the adsorption hole 114h. Although FIG. 4 illustrates that the chip adsorption holes 112h have the same size, another embodiment may include the chip adsorption holes 112h having different sizes. In addition, although FIG. 4 illustrates that the chip adsorption holes 112h have the same intervals, in another example, intervals of the chip adsorption holes 112h may be different from each other. Various other variations are possible.

Sizes, planar shapes, or the like of the chip adsorption hole 112h and the adsorption hole 114h may be variously modified in consideration of sizes of the second bottom portion 112b and the adsorption portion 114b, the intended negative pressure to be applied, or a vacuum pressure provided to the inner space portion 100s, or the like.

FIG. 5 is a plane view schematically illustrating the adsorption device 100 according to another embodiment. For a clear understanding, in FIG. 5, a region where the semiconductor chip 220 included in the semiconductor package is disposed is indicated by a dotted line.

Referring to FIG. 5, the adsorption device 100 according to the embodiment may include a first portion 1141 in which the substrate adsorption portion 114 is disposed at the dummy region 204b of FIG. 2A of the outer region 204 of FIG. 2A and a second portion 1142 disposed at the edge region 204a of FIG. 2A. The bottom portion 112 may be disposed at a region including the semiconductor chip 220, and the substrate adsorption portion 114 protruding from the bottom portion 112 may be disposed at a portion corresponding to the dummy region 204b and the edge region 204a of the outer region 204.

The adsorption hole 114h may be provided at the first portion 1141 corresponding to the dummy region 204b, and an additional adsorption hole 114g may be provided at the second portion 1142 corresponding to the edge region 204a.

Accordingly, the first portion 1141 of the substrate adsorption portion 114 may be adhered and fixed to the dummy region 204b at the upper surface 210a of FIG. 1 of the substrate 210 of FIG. 1 included in the semiconductor package 200 of FIG. 1 by the adsorption hole 114h, and the second portion 1142 of the substrate adsorption portion 114 may be adhered and fixed to the edge region 204a at the upper surface 210a of the substrate 210 included in the semiconductor package 200 by the additional adsorption hole 114g. When the substrate adsorption portion 114 of the adsorption device 100 is entirely adhered to the outer region 204 of the semiconductor package 200, an adsorption area may be increased so that the adsorption device 100 is more stably adhered to the semiconductor package 200.

The additional adsorption hole 114g may be formed to pass through the second portion 1142, and may be formed to fluidly communicate with the first space portion disposed inside the substrate adsorption portion 114. For example, a plurality of additional adsorption holes 114g may have the same shape and the same size, and may be disposed at equal intervals. When the plurality of additional adsorption holes 114g are provided, a difference in deformation due to a difference in pressure may be minimized.

For example, a diameter or a width of the additional adsorption hole 114g may be about 10 μm to about 10 mm. Here, the diameter or the width of the additional adsorption hole 114g may mean a maximum diameter or a maximum width. When the diameter or the width of the additional adsorption hole 114g is less than 10 μm, an adsorption force of the second portion 1142 may not be sufficient. When the diameter or the width of the additional adsorption hole 114g exceeds 10 mm, a degree of deformation may be different between a portion where the additional adsorption hole 114g is disposed and a portion where the additional adsorption hole 114g is not disposed, and a risk of vacuum breakage or a risk of leakage may be high. However, the above-described numerical range of the diameter or the width of the additional adsorption hole 114g is only presented as an example, and the embodiment is not limited thereto.

A size of the additional adsorption hole 114g may be the same as or larger or smaller than a size of the adsorption hole 114h. For example, the additional adsorption holes 114g may be formed equal to or larger than the adsorption holes 114h, so that the plurality of additional adsorption holes 114g constitute one row along the edge region 204a. Then, the adsorption device 100 may be uniformly adhered using a small number of additional adsorption holes 114g along a relatively narrow edge region 204a. However, the embodiment is not limited thereto.

The additional adsorption hole 114g may have any of various planar shapes, such as a circular shape, an elliptical shape, a rounded shape, a polygonal shape, an irregular shape, and the like. A planar shape of the additional adsorption hole 114g may be the same as or different from that of the adsorption hole 114h. Although FIG. 5 illustrates that the additional adsorption holes 114g have the same size, another embodiment may include the additional adsorption holes 114g having different sizes. In addition, although FIG. 5 illustrates that the additional adsorption holes 114g have the same intervals, in another example, intervals of the additional adsorption holes 114g may be different from each other. Various other variations are possible.

Sizes, planar shapes, intervals, or the like of the additional adsorption hole 114g and the adsorption hole 114h may be variously modified in consideration of a size of the edge region 204a or the second portion 1142, a size of a negative pressure or a size of a vacuum pressure provided to the inner space portion 100s, or the like.

FIG. 5 illustrates that the additional adsorption hole 114g is provided together with the adsorption hole 114h and the chip adsorption hole 112h of FIG. 4 is not formed at the second bottom portion 112b. Accordingly, the chip adsorption hole 112h may not be provided at the second bottom portion 112b so that the bottom portion 112 has sufficient rigidity, and the adsorption device 100 may be stably fixed by the adsorption hole 114h and the additional adsorption hole 114g. The embodiment is not limited thereto. Therefore, in the embodiment of FIG. 5, the chip adsorption hole 112h shown in FIG. 4 may be additionally provided at the second bottom portion 112b.

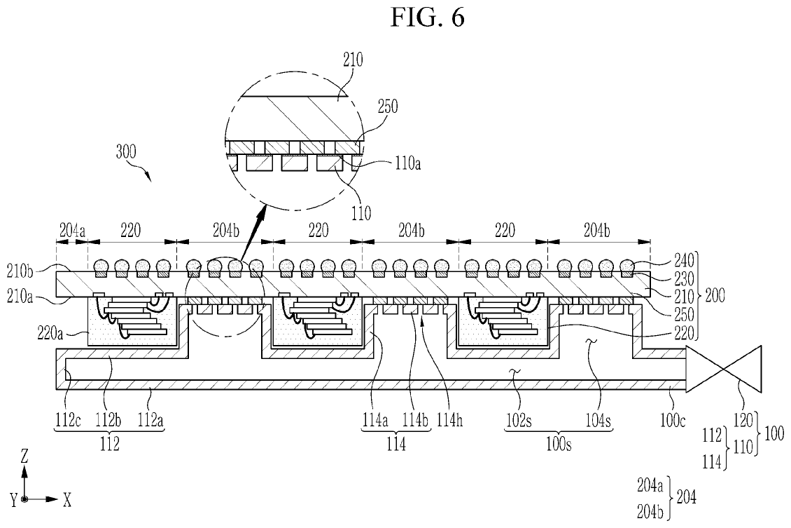

FIG. 6 is a cross-sectional view schematically illustrating the reflow assembly 300 in which the adsorption device 100 is coupled to the semiconductor package 200 according to another embodiment.

Referring to FIG. 6, the semiconductor package 200 to which the adsorption device 100 according to the embodiment is adhered may include a plurality of dummy pads 250 provided at the outer region 204 (more specifically, the dummy region 204b) on the upper surface 210a of the substrate 210.

Here, the dummy pad 250 may be a pad connected to a separate semiconductor element, a separate semiconductor chip, a separate electronic component, or the like that will later be disposed at the dummy region 204b. For example, the plurality of dummy pads 250 may be provided at one dummy region 204b. However, the embodiment is not limited thereto, and one dummy pad 250 may be provided at the one dummy region 204b or no dummy pad 250 may be provided.

The plurality of adsorption holes 114h corresponding to (e.g., one-to-one corresponding to) the plurality of dummy pads 250 may be provided at the substrate adsorption portion 114, and more specifically, the adsorption portion 114b, of the adsorption device 100. The substrate adsorption portion 114 serving as the dummy chip or the artificial chip may be stably adhered to the dummy pad 250. Even if a structure, such as the dummy pad 250, is disposed at the dummy region 204b on the upper surface 210a of the substrate 210, the substrate adsorption portion 114 may be stably attached above the substrate 210 by adjusting a position, a size, or the like of the adsorption hole 114h.

Accordingly, in the reflow process, a difference in thermal expansion between the region where the semiconductor chip 220 is disposed and the outer region 204 where the semiconductor chip 220 is not disposed may be minimized. As a result, a problem caused by the difference in thermal expansion may be reduced or prevented.

For example, a thermal conductive layer 110a may be further provided at a surface of the main body 110 or the adsorption portion 114b of the substrate adsorption portion 114 that is adjacent to the dummy pad 250. The thermal conductive layer 110a may include a thermal conductive material or a thermal conductive layer having higher thermal conductivity than the substrate 210, the main body 110, or the adsorption portion 114b of the substrate adsorption portion 114. For example, the main body 110 or the adsorption portion 114b may be made of stainless steel, and the thermal conductive layer 110a may be made of a metal such as copper or the like. Then, heat may be more effectively dissipated by the thermal conductive layer 110a. The thermal conductive layer 110a may be formed on the main body 110 or the adsorption portion 114b by coating or the like, or may be attached on the main body 110 or the adsorption portion 114b by an adhesive layer or the like.

The adsorption portion 114b of the substrate adsorption portion 114 may have high thermal conductivity. Thus, heat may be effectively transferred or discharged through the main body 110 in the reflow process, so that thermal deformation of the substrate 210 is effectively prevented. For example, a heat conduction path may be formed through the dummy pad 250 and the substrate adsorption portion 114 to enable effective heat transfer.

FIG. 6 illustrates that the dummy pad 250 is on the upper surface 210a of the substrate 210 to protrude beyond the upper surface 210a of the substrate 210. However, the embodiment is not limited thereto, and an upper surface of the dummy pad 250 may be on the same plane as the upper surface 210a of the substrate 210. Various other variations are possible.

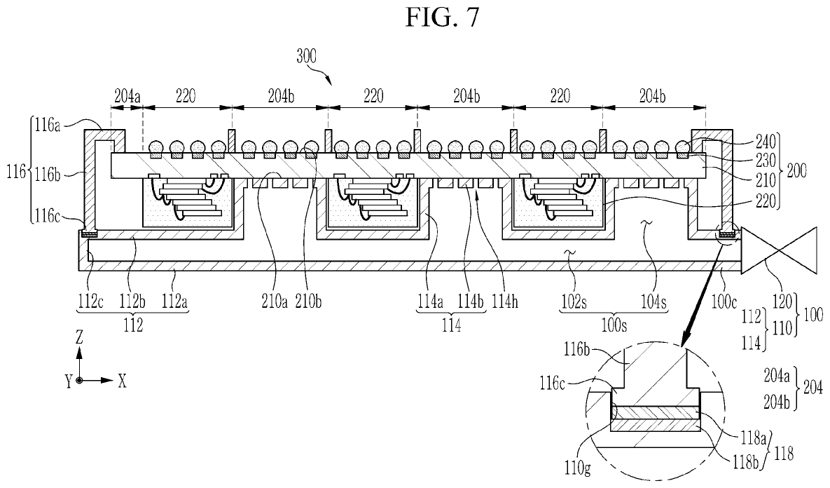

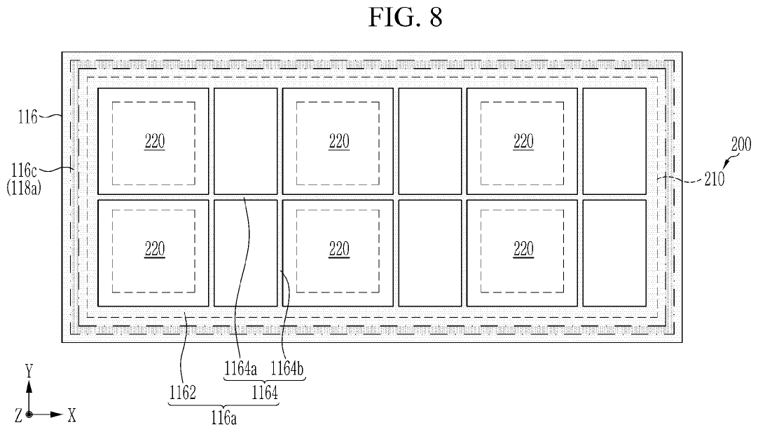

FIG. 7 is a cross-sectional view schematically illustrating the reflow assembly 300 in which the adsorption device 100 is coupled to the semiconductor package 200 according to another embodiment, and FIG. 8 is a plane view schematically illustrating a fixing portion 116 of the adsorption device 100 and the semiconductor package 200 shown in FIG. 7. FIG. 8 is the plane view illustrating the lower surface 210b of the substrate 210 included in the semiconductor package 200 and the fixing portion 116, and the connection bump 240 is omitted from FIG. 8 for a brief illustration.

Referring to FIGS. 7 and 8, the adsorption device 100 according to the embodiment may include the fixing portion 116 including a portion disposed at the lower surface 210b of the substrate 210 and a coupling member 118 connecting the main body 110 and the fixing portion 116 together with the main body 110 disposed at the upper surface 210a of the substrate 210.

In various embodiments, the fixing portion 116 may include a fixing part 116a disposed on the lower surface 210b of the substrate 210, an extension portion 116b extending from the fixing part 116a toward the upper surface 210a of the substrate 210, and an insertion portion 116c disposed at an end portion of the extension portion 116b and inserted into an insertion groove 110g formed at the main body 110. A first coupling member 118a may be disposed at one surface of the insertion portion 116c facing the main body 110.

In various embodiments, the fixing part 116a on the lower surface 210b of the substrate 210 may include an edge fixing portion 1162 formed along an edge of the substrate 210 and an internal fixing portion 1164 formed across an internal region of the substrate 210. The internal fixing portion 1164 may be disposed above or on the lower surface 210b of the substrate 210 at a portion where the semiconductor chip 220 and the connection bump 240 are not provided.

For example, the internal fixing portion 1164 may include one or more of first internal fixing portions 1164a extending along the first direction (the X-axis direction in the drawings) and one or more of second internal fixing portions 1164b extending along the second direction (the Y-axis direction in the drawings). When the internal fixing portion 1164 has a grid shape including portions crossing each other, the lower surface 210b of the substrate 210 may be more stably fixed. However, the embodiment is not limited thereto, and only one of the first and second internal fixing portions 1164a and 1164b may be provided, or the first and second internal fixing portions 1164a and 1164b may not be provided.

In various embodiments, the insertion portion 116c may be expanded, so that the first coupling member 118a has a sufficient area, and may be expanded to have a larger area than the extension portion 116b. However, the embodiment is not limited thereto, and the insertion portion 116c may have a different shape.

The insertion groove 110g having the same area as the insertion portion 116c may be formed at the main body 110, and a second coupling member 118b coupled to the first coupling member 118a may be disposed at an inner surface (e.g., a bottom surface) of the insertion groove 110g.

In an embodiment, the extension portion 116b, the insertion portion 116c, and the first coupling member 118a provided in the insertion portion 116c may be entirely formed along an edge of the adsorption device 100. For example, when the extension portion 116b, the insertion portion 116c, and the first coupling member 118a are viewed in a plane, the extension portion 116b, the insertion portion 116c, and the first coupling member 118a may have a frame shape in which the semiconductor package 200 is disposed inside the extension portion 116b, the insertion portion 116c, and the first coupling member 118a. In addition, the insertion groove 110g and the second coupling member 118b provided in the insertion groove 110g may be formed as a whole along an edge of the adsorption device 100 so as to correspond to the insertion portion 116c and the first coupling member 118a provided in the insertion portion 116c. Accordingly, the main body 110 and the fixing portion 116 may be fixed at an entire edge so that fixing stability is improved.

In various embodiments, the first coupling member 118a and the second coupling member 118b may be made of a magnetic material capable of being coupled to each other by a magnetic force. Then, the main body 110 and the fixing portion 116 may be stably fixed by a simple structure. However, the embodiment is not limited thereto, and coupling structures, coupling methods, or the like of the first and second coupling members 118a and 118b may be variously modified.

As shown in FIGS. 3A and 3B, after the main body 110 of the adsorption device 100 is adhered and coupled to the upper surface 210a of the substrate 210, the fixing portion 116 may be on the lower surface 210b of the substrate 210, so that the main body 110 and the fixing portion 116 are fixed using the first and second coupling members 118a and 118b. The fixing portion 116 may be fixed to the main body 110 before a process of forming the connection bump 240 or after the process of disposing the connection bump 240. The reflow process may be performed in a state in which the fixing portion 116 is fixed to the main body 110, and the fixing portion 116 and the main body 110 may be separated from the semiconductor package 200 after the reflow process. The fixing portion 116 and the main body 110 may be easily separated by providing a force greater than the magnetic force, and the main body 110 and the semiconductor package 200 may be easily separated by vacuum breakage.

Because the adsorption device 100 can have a structure in which the main body 110 and the fixing portion 116 are combined to fix the upper surface 210a and the lower surface 210b of the substrate 210 included in the semiconductor package 200 together, the adsorption device 100 may be more firmly fixed to the substrate 210 in the reflow process. In this case, the fixing portion 116 may be prevented from moving on a plane by inserting the insertion portion 116c into the insertion groove 110g, and the main body 110 and the fixing portion 116 may be prevented from being separated from each other in a vertical direction by the first and second coupling members 118a and 118b.

FIG. 9 is a cross-sectional view schematically illustrating the reflow assembly 300 in which the adsorption device 100 is coupled to the semiconductor package 200 according to another embodiment.

Referring to FIG. 9, the adsorption device 100 according to the embodiment may include a plurality of inner space portions 100s separated from each other by a partition member 100p, and may include a plurality of pressure control members 120 respectively connected to the plurality of inner space portions 100s. The partition member 100p may be integrally formed with the first bottom portion 112a and/or the second bottom portion 112b, and may be formed separately from the first bottom portion 112a and the second bottom portion 112b to be disposed between the first bottom portion 112a and the second bottom portion 112b.

When the pressure control member 120 is separately provided by dividing the inner space portion 100s into a plurality of portions, as described above, the adsorption device 100 may be more firmly adhered and fixed to the semiconductor package 200 by stably providing a negative pressure or vacuum pressure to each inner space portion 100s.

For example, as shown in FIG. 9, the partition member 100p may be extended in the second direction (the Y-axis direction in the drawings) to divide the inner space portion 100s into a plurality of spaces in the first direction (the X-axis direction in the drawings), and the pressure control members 120 may be respectively provided at short axis edges disposed at both sides of the first direction. For example, when the inner space portion 100s is divided into two in the first direction, the pressure control member 120 connected to the divided inner space portion may be disposed at the short axis edge. However, the embodiment is not limited thereto, the inner space portion 100s may be divided into three or more in the first direction, and the pressure control member 120 may be disposed at the short axis edge or a long axis edge.

As another example, as shown in FIG. 10, the partition member 100p may include a first partition member 102p extending in the first direction (the X-axis direction in the drawings) and a second partition member 104p extending in the second direction (the Y-axis direction in the drawings), and the plurality of pressure control members 120 may be disposed to correspond one-to-one to a plurality of inner space portions partitioned by the first and second partition members 102p and 104p. For example, FIG. 10 illustrates that an inner space portion is divided into two in the second direction, so that two pressure control members 120 are respectively disposed at the short axis edges disposed at both sides of the first direction. However, the embodiment is not limited thereto, and the inner space portion may be divided into three or more in the second direction so that three or more pressure control members 120 are disposed at the short axis edge. The central positions of the first partition member 102p and the second partition member 104p are schematically indicated in FIG. 10 for illustrative purposes only.

In various embodiments, the partition member 100p may include only the first partition member 102p without the second partition member 104p. A plurality of pressure control members 120 may be disposed at the short axis edge disposed at one side, and some of a plurality of pressure control members 120 may be disposed at the short axis edge disposed at one side and others of the plurality of pressure control members 120 may be disposed at the short axis edge disposed at the other side. Various other variations are possible.

In addition, the above description illustrates that one pressure control member 120 is provided at one inner space portion 100s (refer to FIG. 9), but the embodiment is not limited thereto. The plurality of pressure control members 120 may be provided at one inner space portion 100s to stably provide a negative pressure or a vacuum pressure to the inner space portion 100s. Various other variations are possible.

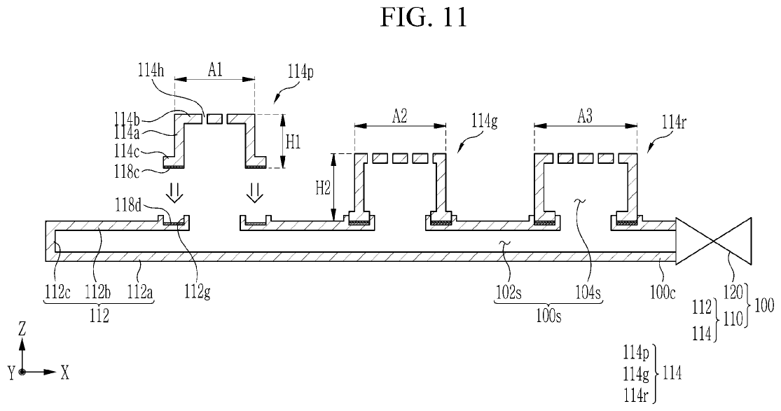

FIG. 11 is a cross-sectional view schematically illustrating the adsorption device 100 according to another embodiment.

Referring to FIG. 11, in the adsorption device 100 according to the embodiment, the main body 110 may have a size control structure for adjusting a size of the substrate adsorption portion 114.

In various embodiments, the substrate adsorption portion 114 may have a separable structure in which the substrate adsorption portion 114 is detachable from the bottom portion 112. The main body 110 may include coupling members 118c and 118d to which the bottom portion 112 and the substrate adsorption portion 114 of the separable structure can be coupled. The substrate adsorption portion 114 with the separable structure and the coupling members 118c and 118d may constitute the size control structure.

More specifically, the substrate adsorption portion 114 may include the side portion 114a, the adsorption portion 114b connected to one side of the side portion 114a to be adhered to the substrate 210, and the insertion portion 114c connected to the other side of the side portion 114a. A third coupling member 118c may be disposed at one surface of the insertion portion 114c facing the bottom portion 112.

For example, the insertion portion 114c may be expanded, so that the third coupling member 118c has a sufficient area, and may be expanded to have a larger area than the side portion 114a. However, the embodiment is not limited thereto, and the insertion portion 114c may have a different shape. The insertion portion 114c may be formed along an entire edge at the other side of the side portion 114a, and may be a kind of flange including an expansion portion extending to the outside of the side portion 114a.

An insertion groove 112g having the same area as the insertion portion 114c may be formed at the bottom portion 112, and a fourth coupling member 118d coupled to the third coupling member 118c may be disposed at an inner surface (e.g., a bottom surface) of the insertion groove 112g. The insertion groove 112g and the fourth coupling member 118d provided in the insertion groove 112g may be formed to correspond to the insertion portion 114c and the third coupling member 118c provided in the insertion portion 114c. Accordingly, the bottom portion 112 and the substrate adsorption portion 114 may be fixed at an entire edge so that fixing stability is improved.

For example, the third coupling member 118c and the fourth coupling member 118d may be made of a magnetic material capable of being coupled to each other by a magnetic force. Then, the bottom portion 112 and the substrate adsorption portion 114 may be stably fixed by a simple structure. However, the embodiment is not limited thereto, and coupling structures, coupling methods, or the like of the third and fourth coupling members 118c and 118d may be variously modified.

The substrate adsorption portion 114 may be fixed to the bottom portion 112 by inserting the insertion portion 114c of the substrate adsorption portion 114 into the insertion groove 112g of the bottom portion 112. The substrate adsorption portion 114 may be prevented from moving on a plane by inserting the insertion portion 114c into the insertion groove 112g, and the bottom portion 112 and the substrate adsorption portion 114 may be prevented from being separated from each other in a vertical direction by the third and fourth coupling members 118c and 118d. When separation of the substrate adsorption portion 114 is intended, the substrate adsorption portion 114 may be separated from the bottom portion 112 by providing a force greater than the magnetic force to the substrate adsorption portion 114.

In an embodiment, the substrate adsorption portion 114 with the separable structure may include a plurality of separable adsorption portions 114p, 114q, and 114r having different sizes. Depending on a design of the semiconductor package, the separable adsorption portion 114p, 114q, or 114r with an appropriate size may be selected from the plurality of separable adsorption portions 114p, 114q, and 114r so that the selected separable adsorption portion is fixed to the bottom portion 112.

In various embodiments, the first adsorption portion 114p may have a first area A1, the second adsorption portion 114q may have a second area A2 larger than the first area A1, and the third adsorption portion 114r may have a third area A3 larger than the second area A2. Areas of the first to third adsorbing portions 114p, 114q, and 114r may be different by changing a position of the side portion 114a at the insertion portion 114c. The areas of the first to third adsorption portions 114p, 114q, and 114r may be freely adjusted, while maintaining an area and a position of the insertion portion 114c. Accordingly, the area of the substrate adsorption portion 114 may be adjusted by attaching the separable adsorption portions 114p, 114q, and 114r having desired areas to the bottom portion 112 without changing the bottom portion 112.

In various embodiments, the plurality of separable adsorption portions 114p, 114q, and 114r may have different heights. For example, the first adsorption portion 114p may have a first height H1, and the second adsorption portion 114q may have a second height H2 greater than the first height H1. Accordingly, a height of the substrate adsorption portion 114 may be adjusted by combining the adsorption portions 114p, 114q, and 114r having desired heights with the bottom portion 112.

The above description illustrates that the size control structure is implemented using the substrate adsorption portion 114 with the separable structure. Accordingly, because the substrate adsorption portion 114 with the separable structure having a desired size is manufactured, so that the manufactured substrate adsorption portion is coupled to the bottom portion 112, it is not necessary to manufacture the main body 110 as a whole. Accordingly, the embodiment may be easily applied to the semiconductor package having different designs to include outer regions with various sizes.

However, the embodiment is not limited thereto, and the size control structure may be implemented by another structure or method. For example, the main body 110 may have a variable structure in which a size or a shape of the substrate adsorption portion 114 may be changed. For example, the substrate adsorption portion 114 may include a material, a structure, or the like in which a size or a shape is changed by a pressure or an external force. Various other variations are possible.

FIG. 12 is a cross-sectional view schematically illustrating the reflow assembly 300 in which the adsorption device 100 according to the embodiment is coupled to a semiconductor package 200a according to a modified example.

Referring to FIG. 12, the adsorption device 100 according to the embodiment may be coupled to the semiconductor package 200a using a flip-chip bonding method to form the reflow assembly 300.

More specifically, in the semiconductor package 200a, the semiconductor chip 220 may be mounted at the upper surface 210a of the substrate 210 by the flip-chip bonding method. A bump 220b may be disposed between a lower surface of the semiconductor chip 220 and the upper surface 210a of the substrate 210 so that the semiconductor chip 220 and the substrate 210 are connected to each other. A pad where the bump 220b is disposed may be provided at the lower surface of the semiconductor chip 220 and the upper surface 210a of the substrate 210, and a sealing portion or an under-fill portion filling a gap between the semiconductor chip 220 and the substrate 210 may be provided. As described above, when the semiconductor package 200a has the flip-chip bonding method, an electrical connection path may be reduced and the number of input/output terminals may be increased.

In this case, the bump 220b may have various shapes, such as a ball, a land, a pin, and the like, and may include tin or an alloy (e.g., a Sn—Ag—Cu alloy) including tin. However, the embodiment is not limited thereto, and the semiconductor chip 220 and the substrate 210 may be connected to each other by any of various structures.

In various embodiments, the adsorption device 100 may be coupled to the semiconductor package 200 or 200a having any of various structures to form the reflow assembly 300. Although FIG. 12 illustrates that the adsorption device 100 has the structure shown in FIG. 1 as an example, the adsorption device 100 may have the structure according to the embodiment described with reference to FIGS. 4 to 11.

The above-described embodiment illustrates that the adsorption device 100 or the vacuum jig according to the embodiment can be coupled to the semiconductor package 200 or 200a to be used in the reflow process. However, the embodiment is not limited thereto, and the adsorption device 100 or the vacuum jig according to the embodiment may be coupled to a semiconductor chip, a semiconductor element, the semiconductor package 200 or 200a, or the like to be used in any of various semiconductor processes forming the semiconductor chip, the semiconductor element, the semiconductor package 200 or 200a, or the like.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An adsorption device, comprising:
a main body that includes an inner space portion, a bottom portion, and a substrate adsorption portion that protrudes from the bottom portion, wherein the substrate adsorption portion is configured to adhere to a first surface of a substrate by a negative pressure; and
a pressure control member that maintains a pressure of the inner space portion.

2. The adsorption device of claim 1, wherein one or more adsorption holes are formed in the substrate adsorption portion.

3. The adsorption device of claim 1, wherein the pressure control member maintains the inner space portion in a vacuum state, wherein the adsorption device maintains adherence to the substrate during a reflow process, and separates from the substrate by breaking the vacuum of the inner space portion subsequent to the reflow process.

4. The adsorption device of claim 1, wherein the substrate adsorption portion is adhered to the first surface of the substrate to be a dummy chip or an artificial chip in a reflow process.

5. The adsorption device of claim 1, wherein the substrate includes a plurality of semiconductor chips on the first surface, wherein the substrate adsorption portion is configured to adhere between a dummy region each adjacent pair of the plurality of semiconductor chips, and wherein an adhesion area of the substrate adsorption portion is 50% to 95% of the dummy region.

6. The adsorption device of claim 1, wherein the pressure control member includes a valve.

7. The adsorption device of claim 1, wherein the semiconductor package further includes a plurality of dummy pads provided at the outer region on the first surface of the substrate, and the substrate adsorption portion includes a plurality of adsorption holes provided to respectively correspond to the plurality of dummy pads.

8. The adsorption device of claim 1, further comprising a chip adsorption hole formed in the bottom portion, wherein the bottom portion is configured to adhere to a semiconductor chip on the substrate.

9. The adsorption device of claim 1, further comprising:
a fixing portion that includes a portion disposed at the other surface of the substrate opposite to the first surface of the substrate; and
a coupling member fixing the main body and the fixing portion.

10. The adsorption device of claim 1, wherein the inner space portion includes a plurality of inner space portions, and the pressure control member includes a plurality of pressure control members respectively connected to the plurality of inner space portions.

11. The adsorption device of claim 1, wherein the main body has a size control structure configured for adjusting a size of the substrate adsorption portion.

12. The adsorption device of claim 11, wherein the substrate adsorption portion has a separable structure in which the substrate adsorption portion is detachable from the bottom portion.

13. The adsorption device of claim 1, wherein the adsorption device has a long axis edge and a short axis edge that intersect, and the pressure control member is fluidly connected to the short axis edge.

14. The adsorption device of claim 1, wherein the main body includes stainless steel, ceramic, a thermal conductive layer, or a combination thereof.

15. A vacuum jig for a semiconductor package, comprising:
a main body that includes an inner space portion and includes a bottom portion and a substrate adsorption portion protruding from the bottom portion, wherein the substrate adsorption portion includes one or more adsorption holes; and
a vacuum control member configured to control a vacuum state of the inner space portion.

16. A method for forming a connection bump, comprising:
forming a reflow assembly by coupling an adsorption device to a semiconductor package including a substrate and a semiconductor chip on a first surface of the substrate;
forming the connection bump on a second surface of the substrate opposite the first surface;
performing a reflow process of coupling the connection bump to the second surface of the substrate by applying heat to the connection bump; and
separating the adsorption device from the semiconductor package,
wherein in the forming of the reflow assembly, a substrate adsorption portion of the adsorption device is adhered to an outer region of the semiconductor chip on the first surface of the substrate.

17. The method of claim 16, wherein the adsorption device includes a main body including an inner space portion and a pressure control member that controls a pressure of the inner space portion, and the main body includes a bottom portion and the substrate adsorption portion protruding from the bottom portion.

18. The method of claim 16, wherein in the forming of the reflow assembly, an inner space portion of the adsorption device is made into a vacuum state in a state in which the adsorption device is disposed on the semiconductor package, so that the adsorption device is adhered and coupled to the semiconductor package.

19. The method of claim 18, wherein the separating of the adsorption device is performed by breaking vacuum of the inner space portion.

20. The method of claim 16, wherein in the performing of the reflow process, the reflow assembly moves on a conveyor belt.
